(19) United States
(12) Patent Application Publication
(10) Pub. No.: US 2025/0133661 A1
(43) Pub. Date: Apr. 24, 2025

(54) MASKING METHOD AND MASKED PRODUCT

(71) Applicant: P2i Ltd, Abingdon, Oxfordshire (GB)

(72) Inventors: Graham HUBBARD, Abingdon (GB); Alex MCLEOD, Abingdon (GB); Victoria SULLIVAN, Abingdon (GB); Ciaran WILSON, Abingdon (GB)

(73) Assignee: P2i Ltd, Abingdon, Oxfordshire (GB)

(21) Appl. No.: 18/835,688

(22) PCT Filed: Feb. 3, 2023
(86) PCT No.: PCT/EP2023/052665

§ 371 Date: Aug. 2, 2024

(30) Foreign Application Priority Data
Feb. 4, 2022 (GB) 2201486.4

(51) Int. Cl. H05K 3/00; H05K 1/18; H05K 3/28; H05K 3/32; H05K 3/34

(52) U.S. Cl. CPC H05K 3/0079; H05K 1/184; H05K 3/0076; H05K 3/285; H05K 3/288; H05K 3/325; H05K 3/3447; H05K 2201/0133; H05K 2201/015; H05K 2201/0166; H05K 2201/09872; H05K 2201/0989; H05K 2201/10053; H05K 2203/095; H05K 2203/162

(57) ABSTRACT

Methods to mask an RF switch prior to a coating process and RF switches that have been masked according to these methods.

### TECHNICAL FIELD

This invention relates to the masking of radiofrequency (RF) switches. In particular, though not exclusively, the invention relates to a method to mask an RF switch prior to a coating process. Other aspects of the invention relate to a masked radiofrequency switch producible according to the method and a printed circuit board comprising such a switch.

### BACKGROUND

Radiofrequency (RF) switches are 3-dimensional printed circuit board (PCB) components that are used for quality control assessment of the correct operation of radiofrequency-handling circuitry of the PCB. RF switches are most often used to verify that PCBs with signaling capability are correctly shielded from over the air (OTA) signals. To do this, a test probe is used to actuate the RF switch, and this breaks the connection between the radiofrequency-handling circuitry and the antenna. In addition, this actuation can connect the radiofrequency circuitry and/or antenna to test probe circuitry. This allows for the radiofrequency circuitry and/or the antenna to be tested under a variety of external RF conditions, test circuitry conditions, and/or on-board circuitry conditions. RF switches therefore find use in a wide range of electronic devices and are ubiquitous in electronic devices having OTA capacity.

The function of the RF switches is utilised at discrete steps in the post surface mount stage (post-SMT) of PCB assembly. RF switches are initially utilised for the quality control stages of manufacture. When in use by an end consumer, actuation of the RF switch serves no useful function. Of course, when in use by an end consumer RF switches should reliably remain in a state where the antenna and RF circuitry are connected. RF switches find utility once again after use by the end consumer during re-working of the PCB, in which case correct functioning of the RF switch under test probe conditions will be required once again (to avoid steps of fault-finding and having to de-solder the RF switch and solder a new RF switch to the PCB ahead of further testing).

RF switches utilise delicate electromechanical micro-components and often have an open structure, a small size and weak solder joints to the PCB, which make them very sensitive to damage from external factors. RF switches and their delicate internal components are particularly at risk from becoming blocked or corroded by contaminants and/or detaching from the PCB. This may be caused by any of a wide variety of external factors including physical shock, dust, manual handling, and so on. This can adversely affect both the required operation by the end user (if the antenna-RF circuitry connection is broken) as well as the required operation under test conditions (if the ability to respond properly to the test probe is compromised).

A recent area of significant activity in the electronic device sector has been to make electronics devices, particularly portable electronics, water-resistant. Water-resistance has become a highly desirable feature of a range of electronics devices, and is used to protect devices such as mobile telephones, tablets, smart watches, earphones, and the like, from water damage. A key technology to provide water-resistance has been to coat finished electronics devices and their circuit boards by depositing upon them a layer of water-resistant polymer. A particularly effective waterproofing technique involves deposition of a plasma polymerised material (described, for example, in WO 2007/083122, WO 2016/198855, WO 2016/198957 or WO 2020/169975). Depending on the specific coating used, electronics devices can be made resistant to splashes of water or can be made water resistant such that they remain fully functional when fully immersed in water for a period of time.

Unfortunately, however, the higher performance coating technologies that are becoming increasingly used in the electronics sector have been found to coat RF switches with an electrically insulating layer. While operation by an end user is unaffected, the RF switches cannot be used in quality control of re-worked PCBs as the test probe cannot form an electrical contact with the switch plate. Attempts to remove the coating often destroys the RF switches.

Technologies for masking components ahead of coating are known. For instance, WO 2019/175586 describes dispensing a silicone rubber over electrical components ahead of coating, and then making electrical connections by passing connectors through the silicone rubber. However, those connections are intended to form the final assembly and are not compatible with test probes that are introduced and withdrawn in the re-work cycle, as this would cause contamination of the probe.

It is therefore a challenge to protect these delicate RF switches such that they retain their function in various settings; including:
(1) Original manufacture—desirable that RF switch operates under test conditions,
(2) End user use—desirable that there is no disruption of antenna-RF circuitry connection in units shipped to end user,
(3) End user use—desirable that there is no disruption of antenna-RF circuitry when exposed to contaminants such as water, and
(4) Re-work cycle—desirable that RF switch operates under test conditions.

It is an object of the invention to provide a method that solves one or more of the above-mentioned problems, or another problem associated with the prior art.

### SUMMARY OF THE INVENTION

According to a first aspect, the present invention provides a method of masking a PCB-mounted radiofrequency switch for a subsequent coating process, wherein the radiofrequency switch comprises a receptacle comprising a probe access port and one or more side ports, the receptacle having an electromechanical component therein, and the receptacle being shaped for receiving a probe through the probe access port to actuate the electromechanical component, wherein the method comprises flowing a curable masking material into the probe access port and thereby through the receptacle into the one or more side ports, and curing the masking material to form a removable elastic masking plug.

The present invention can therefore provide a new masking technique whereby RF switches can be protected from damaging effects of coating processes. The masking plug can remain in place throughout a coating process, and optionally throughout use by an end user, and yet be removed without damaging the RF switch allowing it to be used in a re-work cycle.

In initial trials, the inventors made attempts to mask an RF switch using techniques such as liquid masking and/or compression or grommet masking. As described in further detail in the examples, these were determined to be inappropriate. In some cases, the RF switches would be located too close to other surface mounted devices to allow for these techniques to be deployed successfully. In some cases, trapped air was problematic during the vacuum conditions utilised for subsequent deposition of the coating. In some cases, attempted removal of silicone rubber masks was found to render RF switches inoperative. In particular, in the context of radiofrequency switches which have delicate electromechanical components, it is counterintuitive to insert materials into the radiofrequency switches, particularly where those materials may come into contact with the electromechanical components. In this context of the inappropriateness of using masking materials with RF switches, it is particularly surprising that the present invention works so well. Further optional features, definitions and advantages will be set out in further detail below.

### Radiofrequency Switch

By ‘radiofrequency switch’ (or RF switch), we are referring to a microelectronic component that is well-known in the art. The RF switch comprises an actuatable electromechanical component and is thus of the electromechanical type. These microelectronic electromechanical components can be referred to as microelectromechanical components, and can be referred to as a microelectromechanical system (MEMS) component. In some embodiments, the dimensions of an RF switch are up to 3 mm×3 mm×3 mm. In some embodiments the RF switch may be a coaxial RF switch, by which we mean it is configured to receive a coaxial test probe. Suitably, the RF switch may be a microwave switch, by which we mean it can be deployed for operation with frequencies in the microwave region.

The RF switch is mounted on a PCB. Typically, the RF switch is mounted on a PCB using Surface Mount Technology (SMT), an industry standard process by which circuit boards are assembled. Advantageously, the method can allow masking of such a mounted RF switch without detachment and without affecting other components on the PCB. RF switches are often mounted on a PCB using solder joints. These solder joints are often weak and can be broken if excessive force is applied to the RF switch. RF switch solder joints are particularly sensitive to torsion forces applied to the RF switch. The present invention can allow for removal of the elastic masking plug without breaking such solder joints.

### Electromechanical Component

The RF switch comprises a receptacle having an electromechanical component therein. The electromechanical component may constitute all or part of a switch mechanism. In other words, the receptacle can have all or part of a switch mechanism (i.e. the switch mechanism of the RF switch) therein. Conveniently, the electromechanical component may act upon or comprise a switch plate of the RF switch.

In some embodiments, the switch plate forms an electrical connection with a switch plate connector of the switch. The switch plate connector may be fixed in place relative to the RF switch and/or receptacle. All or part of the switch plate may be moveable relative to the switch plate connector, such that the electrical connection between the switch plate and the switch plate connector can be formed or broken by actuation of the electromechanical component.

Suitably, actuation of the electromechanical component may change the state of the RF switch between a closed state and an open state. RF switches are commonly used between an antenna and an RF-processing circuit. For an RF switch, the closed state represents the “on” state where an antenna would be connected to an RF-processing circuit, and the open state represents the “off” state where an antenna would be disconnected from an RF-processing circuit.

In some embodiments, the RF switch may be a biased switch (also termed a momentary action switch). For example, in a neutral (or unactuated) state, a biased RF switch may be in the closed (or ‘on’, or ‘connected’ state). This is known as a Normally Closed (NC) switch or push-to-open switch.

In one embodiment of an NC switch, the electromechanical component acts upon or comprises a switch plate that is suitably resiliently biased such that in the absence of an external force the switch plate is in contact with a switch plate connector. Actuation may be achieved by a probe or other suitable means that can exert force upon the switch plate to counter its bias. In this embodiment, a probe can be used to move the switch plate position and thus change the NC switch to its open (or ‘off’, or ‘disconnected’) state. Upon removal of the actuation, the bias of the switch plate can change the NC switch back to its closed state.

### Probe

The receptacle is shaped for receiving a probe to actuate the electromechanical component. The method of the invention need not include the step of receiving the probe. However, a description of the probe is useful for understanding the invention.

The probe can perform a function of actuating the electromechanical component, and can perform a further function of creating an electrical contact between the RF switch and the probe to allow for test electrical signals to be passed. Often, the RF switch and probe act together to redirect a signal to RF analysis equipment enabling the assembly to be tested (in whatever manner is appropriate for the situation).

Depending on the design of a probe, electrical contact can be made with the electromechanical component or other suitable component of the RF switch in order to form an electrical contact with an RF circuit and/or antenna.

In some embodiments the RF switch may comprise a switch plate and/or switch plate connector comprising probe interface sections for forming electrical connections with a probe. Suitably, such interface sections may face a probe access port of the RF switch. This allows for convenient engagement of the interface section or sections with the probe by lowering the probe into the receptacle. In a preferred embodiment, curable masking material is flowed over one or more, or preferably all, probe interface sections.

### Receptacle

The receptacle is shaped for receiving a probe. A variety of probes are known or conceivable and the receptacle may be any suitable type and configuration.

In some embodiments the RF switch may be a coaxial RF switch, in which case the receptacle may comprise a coaxial connector, in particular a female coaxial connector.

In some embodiments, the receptacle is configured to help protect the electromechanical component of the RF switch from being inadvertently actuated. In some embodiments, the receptable physically shields all or part of the electromechanical component (such as a switch plate and a switch plate connector).

The receptacle comprises a probe access port through which a probe can pass to actuate the electromechanical component. In some embodiments, the receptacle may comprise a guide portion that is configured to guide the probe toward the probe access port and/or locates the probe with respect to the electromechanical component. For instance, in some embodiments the receptacle may comprise a frustoconical wall that directs a probe to the access port. As such, if the probe is off-target, the guide portion can capture and reposition the probe as the probe is lowered into the frustoconical wall.

Where the RF switch is mounted on a PCB, the PCB may be taken as extending in the x-y plane. As such, if the probe is off-target in the x-y plane, the guide portion can capture and guide the probe to a specific position in the x-y plane as the probe is lowered in the z-direction. This requires the off-target probe to still be within an x-y capture radius of the guide portion.

The RF switch, in particular the receptacle, comprises one or more side ports. That is, the RF switch, in particular the receptacle, comprises a probe access port and one or more side ports. In the absence of protection, such side ports provide an access route to the electromechanical component for contaminants such as water. The curable masking material is flowed into the probe access port and thereby flowed through the receptacle into the side ports. As such, the masking material can occupy the receptacle and the one or more side ports. The masking material can thereby mask the electromechanical component. The masking material can mask the electromechanical component by blocking the probe access port and the one or more side ports. The masking material can provide a barrier that prevents coating materials or indeed contaminants from reaching the electromechanical component through the receptacle (i.e. via the probe access port) or through the side ports.

Advantageously, the method can therefore allow masking to occur without affecting other components on the PCB. The method allows for the side ports of an RF switch to be masked without needing to apply masking material to the outside of the sides of the RF switch, to thereby cover the side ports from the outside, which may interfere with other components adjacent to the RF switch on a PCB. In addition, the method allows for the side ports of an RF switch to be masked without needing to access the side ports from the outside of the side ports, which might occur, for example, if positioning an injector near the outside of the side ports to apply masking material over or into the side ports from the outside. Again, space around an RF switch on a PCB is typically limited which blocks access to apply masking material from the outside of a side port using, for example, an injector.

In one embodiment, the one or more side ports comprise side port channels. In one embodiment, the curable masking material is flowed into the probe access port and thereby flowed through the receptacle into the side port channels. The curable masking material may be flowed to fill all or part of each side port channel. In one embodiment, the curable masking material fills only a portion of each side port channel, whereby it masks access to the electromechanical component. In another embodiment, the curable masking material fills substantially all of each side port channel. In a preferred embodiment, the curable masking material flows sufficiently far into the one or more side port channels to mask each side port. It is preferred that the curable masking material flows sufficiently far into each side port channel to allow removal of the masking plug. In particular, it is preferred that the curable masking material flows sufficiently far into each side port channel to allow removal of the masking plug in substantially one piece.

In a preferred embodiment, the masking material is provided through a probe access port into an area of the receptacle having at least one wider dimension than the probe access port. This can provide the masking plug with an anchor against accidental dislodgement. Advantageously, this anchor also allows for the masking plug to remain in place without needing chemical adhesion. In one embodiment, the masking plug does not chemically adhere to the RF switch.

As the RF switch (in particular the receptacle) has one or more access ports (a probe access port and one or more side ports), the inventors have exploited what was previously a weakness of RF switches. Whereas previously these access ports provided an inlet for contaminants, such as liquid access, by flowing the curable masking material into the one or more side ports from the inside and curing, a masking plug is created that is anchored within the RF switch without requiring adhesive, the side ports are blocked without needing to utilise or occupy space around the sides of the RF switch, and yet the masking plug is removable without damaging the RF switch, allowing for the PCB to be used in a rework cycle. The inventors additionally realised that the multiple ports allow for curable masking material to be flowed into the receptacle such that air can be displaced through the other ports such that the number and size of air bubbles can be restricted or prevented. Formation of air bubbles can degrade structural integrity of the mask and/or disrupt the mask under the vacuum conditions used for many coating deposition techniques by the bubbles forcing their way out into the vacuum. In a preferred embodiment there are substantially no trapped air bubbles between the elastic masking plug and receptacle. This development allows for rapid and simple injection of curable masking material without formation of air bubbles.

In addition, this development allows for rapid and reliable use of automation to flow curable masking material into the receptacle. In a preferred embodiment, the method comprises automated flowing of a curable masking material into the receptacle.

The receptacle can be defined by internals of the RF switch. By this, we mean that the RF switch has internals as well as externals. In a preferred embodiment, externals of the RF switch are kept substantially free from masking material. By this, we mean that when the curable masking material is flowed into the receptable, the curable masking material does not flow to or over the externals of the RF switch. This could happen, for example, if the flowable material overspilled the probe access port or flowed out of the side access ports. Keeping the externals of the RF switch substantially free from masking material assists with successful removal of the masking plug. Where an RF switch is mounted on a PCB, this also ensures that masking material does not interfere with other components in close proximity to the RF switch on a PCB. For instance, if the areas adjacent an RF switch on a PCB are subject to ‘keep-out’ restrictions (e.g. PCB edges, optical surfaces or connectors) then overflow of masking material could cause the PCB to fail. As such, the inventors have found a way to successfully deploy masking of an RF switch without masking material reaching areas that could cause problems.

In one embodiment, the receptacle can comprise one or more interstices. In some embodiments, these may be interstices around the electromechanical components. These may be interstices in addition to the side ports and/or side port channels. In a preferred embodiment, the method comprises flowing the masking material into the interstices.

In one embodiment, the receptacle can comprise one or more indirect interstices. By ‘indirect’ we mean that there is at least one interstice that does not have a direct line of sight in the direction a masking plug would be removed. In a preferred embodiment, the method comprises flowing the masking material into one or more indirect interstices. As such, masking material in such indirect interstices will deform should the masking plug be removed in one piece.

### Masking Material

The present invention relates to a method of masking which comprises flowing a curable masking material into the receptacle, and curing the masking material to form a removable elastic masking plug.

Advantageously, the method allows externals of the RF switch, and indeed any other surrounding components such as a PCB upon which the RF switch may be mounted, to remain unmasked by the masking plug.

Suitably, the masking plug may be in contact with internals of the RF switch but not with any externals of the RF switch or any surrounding components.

Conveniently, the method may comprise flowing the curable masking material only into the receptacle. The masking material may then form a masking plug that is in contact only with internals defining the receptacle. Surrounding externals of the RF switch, and indeed any other surrounding components such as a PCB upon which the RF switch may be mounted, may be left substantially unmasked by the masking plug.

The elastic masking plug is formed in the receptacle and can thus mask the electromechanical component. It is particularly preferred that the masking material is flowed onto one or more, preferably all, probe interface sections in the receptacle. As a result, the masking plug can help protect sensitive internal components of the RF switch from damaging effects of a subsequent coating process, and can help to provide protection to sensitive internal components when in use by an end user. The masking plug is removable, thereby allowing successful use of the RF switch during a re-work cycle.

The masking material is curable. By curable, we mean that the masking material is initially in a flowable state, such that it can be flowed into the receptacle. Once in place, the masking material can be cured. In some embodiments, the curable masking material may be a cure-in-place (CIP) masking material. Suitable materials are known in the art and include, for instance, masking materials that can be cured by exposure to air or electromagnetic radiation such as ultraviolet light. Suitable materials also include masking materials that are premixed with a curing agent and set after a period of time, and the masking material is flowed into the receptacle while still in a flowable state. In a preferred embodiment, the masking material is curable by ultraviolet light, as this allows for greater control over timing of the curing and/or thorough curing throughout the material.

This approach is at odds with conventional masking techniques. Instead of applying a mask over the whole RF switch, the mask is flowed into the receptable. In comparison to techniques of the prior art, it is counterintuitive to flow a curable masking material into a receptacle having delicate electromechanical components. However, the inventors have demonstrated that an elastic masking plug formed this way can be retained in place against accidental removal, yet when needed can be removed without detaching the RF switch and without damaging the electromechanical components.

In some embodiments, the method comprises injection of a curable masking material into the receptacle using an injector. Injection can be performed by known means, such as by use of an injector nozzle or injector pen. In one embodiment, the injector can be positioned above the receptacle such that the curable masking material flows into the receptacle when it makes contact with a rim of the receptacle. In one embodiment, the injector may be raised while injecting material. The injector may be raised such that curable masking material is additionally deposited in a guide portion. The injector may be raised such that curable masking material is deposited to create a protrusion.

Advantageously, the injector can take advantage of the design features of the RF switch that engage the probe. In one embodiment, the injector can mimic the probe in dimensions. In one preferred embodiment, the injector can be lowered through the probe access port. In embodiments where the RF switch has a probe guide, the probe guide can be exploited to correctly locate the injector.

In some embodiments, the injector may flow a predetermined amount of curable masking material into the receptacle. In some embodiments, the injector can be withdrawn from the receptacle at an appropriate rate alongside injection. This can allow for the curable masking material to be deposited without sticking to the injector. This can also be exploited to allow for correct formation of a protrusion, if required.

In a particularly preferred embodiment, the method comprises automated injection of a curable masking material into the receptacle using an injector. Automation can benefit from mimicking automation procedures and equipment utilized for a probe (for example, automation can benefit from copying machinery, jigs and RF switch coordinates utilized for a guide probe).

### Removable Elastic Masking Plug

In a preferred embodiment, the elastic masking plug may comprise substantially the entirety of the masking material flowed into the receptacle. In other words, in this embodiment there should not be any masking material in or on the RF switch that is separate from the masking plug. That is, it is preferred that the elastic masking plug is one piece. Furthermore, it is preferable that the elastic masking plug is removable substantially in one piece. In a preferred embodiment, the elastic masking plug is removable without leaving visible contamination. In some embodiments, none, or very little, of the masking plug is left in the RF switch after removal. This minimises residual masking material that can interfere with the RF switch function. While there is some ability for RF switches to function as needed with small amounts of residual masking material, this should reproducibly not interfere with RF switch function when conducted over large batches of RF switches. As such, in some embodiments, residual masking material may be left after removal of the masking plug. In these embodiments, generally, any residual masking material should not interfere with operation of the RF switch. In other words, the RF switch should retain the ability to respond to a test probe in the necessary way, and should remain in the necessary open or closed position in the absence of contact from a test probe. In some embodiments, residual masking material may be left in one or more side ports, in one or more interstices, on the side walls of the receptacle, and/or on the guide portion.

The elastic masking plug is removable. The elastic masking plug is removable if it suitable for removal by a method that avoids damaging the RF switch. In some embodiments, the removable masking plug can be removable by pulling the elastic masking plug from the receptacle. It is generally preferred that the elastic masking plug is removable out of the probe access port. In some embodiments, the elastic masking plug is removable out of the probe access by a pulling force applied to the elastic masking plug. The elastic masking plug can be removable out of the probe access port without damaging the RF switch by a pulling force applied to the elastic masking plug. Any suitable means for applying a pulling force to the elastic masking plug may be used, including applying a pulling force using tweezers.

In a preferred embodiment, the elastic masking plug is formed with a protrusion. The protrusion is above the receptacle in a mounting orientation of the RF switch. It is preferred that the protrusion does not overspill the RF switch. The protrusion can be in the form of a dome or a cone that extends above the RF switch. The protrusion provides a feature that can be manipulated to assist with removal. For instance, the protrusion can be manipulated by tweezers or pierced by a hook, through which gentle force can be applied to remove the masking plug. The height of the protrusion should preferably comply with requirements regarding maximum height of components above a PCB. In one embodiment, the height of the protrusion is preferably 0.25 mm or less above the RF switch. Current RF switches are about 0.7 mm above the height of a PCB, when mounted, and in this case the height of the RF switch plus protrusion is preferably 0.95 mm of less above the PCB. In any event, the skilled person can readily calculate the height of the protrusion above the RF switch, dependent on the height of the RF switch and requirements for the PCBA.

An important feature of the masking plug is that it is elastic. Without wishing to be bound by theory, it is believed that elasticity is important to reducing forces required for removal of the masking plug and allowing the masking plug to flex in relation to sensitive electromechanical components without causing damage to them. Provided with the teaching of the present application, the skilled person can readily identify suitable materials for utilising as the removable masking plug. The skilled person can readily identify suitable materials through testing such materials on the intended RF switch. That is, the elasticity should be such that the masking plug can be removed substantially in one piece (i.e. without tearing), and should be such that the masking plug can be removed without rendering the RF switch inoperative.

In some embodiments, the elastic masking plug has a hardness defined by ASTM D2240-15 of greater than Shore A10, Shore A20, Shore A30, Shore A40, Shore A50, Shore A60 or Shore A70 and less than Shore A140, Shore A130, Shore A120, Shore A110, Shore A100, Shore A90, or Shore A80. In a preferred embodiment, the elastic masking plug has a hardness defined by ASTM D2240-15 of Shore A30 to A100, preferably Shore A40 to A90, more preferably Shore A50 to A80. Shore hardness provides a measure of resistance to indentation, and thus a measure of how much a material may deform under an applied load.

In some embodiments, the elastic masking plug has a modulus of elasticity defined by ASTM D0638-22 of greater than 50 psi, 100 psi, 150 psi, 200 psi, 250 psi, 300 psi, 350 psi, 400 psi, 450 psi, 500 psi, or 550 psi. In some embodiments, the elastic masking plug has a modulus of elasticity defined by ASTM D0638-22 of less than 1500 psi, 1450 psi, 1400 psi, 1350 psi, 1300 psi, 1250 psi, 1200 psi, 1150 psi, 1100 psi, 1050 psi, 1000 psi, 950 psi, 900 psi or 850 psi. In a preferred embodiment, the elastic masking plug has a modulus of elasticity defined by ASTM D0638-22 of 300-2000 psi, more preferably 400 to 1000 psi, yet more preferably 500 to 900 psi, yet more preferably 600 to 800 psi.

In some embodiments, the elastic masking plug has a tensile at break defined by ASTM D0638-22 of greater than 10 psi, 50 psi, 100 psi, 150 psi, 200 psi, 250 psi, 300 psi, 350 psi, 400 psi, or 450 psi. In some embodiments, the elastic masking plug has a tensile at break defined by ASTM D0638-22 of less than 2000 psi, 1700 psi, 1500 psi, 1400 psi, 1300 psi, 1200 psi, 1100 psi, 1050 psi, 1000 psi, 950 psi, 900 psi, 850 psi, 800 psi, 750 psi, 700 psi, 650 psi or 600 psi. In a preferred embodiment, the elastic masking plug has a tensile at break defined by ASTM D0638-22 of 200 to 1500 psi, preferably 300 to 1200 psi, more preferably 400 to 1000 psi.

In some embodiments, the elastic masking plug has an elongation at break defined by ASTM D0638-22 of greater than 50%, 60%, 70%, 80%, or 90%. In some embodiments, the elastic masking plug has an elongation at break defined by ASTM D0638-22 of than 200%, 190%, 180%, 170%, 160% or 150%. In a preferred embodiment, the elastic masking plug has an elongation at break defined by ASTM D0638-22 of 50%-200%, preferably 70%-180%, more preferably 90%-150%.

In a particularly preferred embodiment, the elastic masking plug has a modulus of elasticity defined by ASTM D0638-22 of 500-900 psi, a tensile at break defined by ASTM D0638-22 of 300 to 700 psi, and an elongation at break defined by ASTM D0638-22 of 70%-180%.

A wide number of elastic masking plug materials are suitable for use with the present invention. The skilled person can readily identify such materials. In a preferred embodiment, the masking plug is a polymeric masking plug. In one embodiment, the masking plug is an elastomeric masking plug (i.e. a masking plug that comprises an elastomeric material). In a particularly preferred embodiment, the masking plug comprises a urethane polymer. In a yet more preferred embodiment, the masking plug comprises a urethane acrylate polymer.

In an embodiment, the urethane acrylate polymer comprises one or more additives. For instance, the urethane acrylate polymer may comprise N,N-dimethylacrylamide. In particular, the urethane acrylate polymer may comprise 10-24% by weight N,N-dimethylacrylamide. Without wishing to be bound by theory, it is believed that the N,N-dimethylacrylamide assists with cross-linking. In another example, the urethane acrylate polymer may comprise fumed silica. In particular, the urethane acrylate polymer may comprise 1-5% by weight fumed silica. The inclusion of fumed silica can modulate the pre-cure rheology, and in particular can enhance the shear thinning properties.

The curable masking material preferably has a viscosity defined by ASTM D2556-14 of 20,000-140,000 cP at 20 rpm, 20 deg C. and 1 atm, more preferably 40,000-120,000 cP at 20 rpm, 20 deg C. and 1 atm, yet more preferably 60,000-100,000 cP at 20 rpm, 20 deg C. and 1 atm. In some embodiments it is preferred that the curable masking material has a viscosity high enough to assist with preventing the curable masking material from exiting through the one or more side access ports before it is cured. In some embodiments it is preferred that the viscosity is low enough that the material flows around the electromechanical switch plate without actuation. This avoids the need for waiting for the switch plate to reconnect to the switch plate connector, or actively forcing this reconnection, prior to curing.

In embodiments that employ a protrusion, the viscosity is preferably high enough that the protrusion can hold an appropriate form until curing is complete.

In one embodiment, the curable masking material is thixotropic. That is, the curable masking material can undergo shear thinning. This assists with handling of the curable masking material and flowing of the curable masking material into the receptacle, as flowing of the material can be conducted under the lower viscosity and higher flowability of shear thinning conditions. When in place and static, the curable masking material then reverts to a higher viscosity that allows it to retain an appropriate form until curing is conducted.

### Subsequent Coating Process

The present invention relates to a method of masking a radiofrequency (RF) switch for a subsequent coating process. By ‘coating process’, we are referring to a process that provides an overlying coating of material over the RF switch. The coating process may be a process that would render the RF switch inoperable but for masking.

The method of the invention need not include the coating process. In some embodiments, the method does include the subsequent coating process.

In some embodiments, the overlying coating can protect the RF switch (and any PCBs and/or further components on such PCBs) from: (a) chemical corrosion caused by water and/or corrosive chemicals dissolved within water (such as salt, acids or other corrosive substances); (b) corrosion cause by electrochemical migration; and/or (c) electrical damage caused by short circuiting. In some embodiments, the overlying coating can provide (a) a physical barrier that blocks liquids, and in particular water, from components that can be corroded, and/or (b) electrical insulation over electrically conductive surfaces.

The inventors have found that, in the absence of masking, as long as the RF switch is in a closed state when an overlying coating is applied, then the RF switch can maintain a connection between an antenna and an RF-handling circuit for use by an end user. Further, the RF switch can be successfully protected against water damage by an overlying coating. However, coating tends to render the RF switch unusable in re-work cycles. Coatings are often insulating, which hinders formation of a successful electrical connection with a test probe. The coatings are usually also robust, which means attempted removal of the coatings (for example by attempted scratching off) can often destroy the sensitive electromechanical components of the RF switch, or detach the RF switch from the PCB, rendering the RF switch inoperative.

For all these reasons, the masking provided by the masking plug is essential.

In some embodiments, the overlying coating may have a thickness of at least 100 nm, for example at least 200 nm, or even at least 500 nm. In some embodiments, the overlying coating may have a thickness of less than 2000 nm, for example less than 1500 nm, or even less than 1000 nm.

In some embodiments, the overlying coating may be a barrier coating. A barrier coating provides a barrier against contaminants. The barrier coating may provide a barrier against liquids. In a particularly preferred embodiment, the barrier coating is a barrier against water. In some embodiments, the overlying coating can be electrically insulating, which can protect the unmasked parts of the RF switch against damage by short circuiting (for example, if the contaminant is electrically conductive). In a particularly preferred embodiment, the overlying coating is both a barrier coating and electrically insulating.

The RF switch may be mounted on a PCB, and in such embodiments the coating process may provide an overlying coating over the RF switch, the RF switch masking plug, the PCB, and other components on the PCB.

In various embodiments, the overlying coating may comprise vapour deposited material. The overlying coating may be a polymeric coating. Suitably, the overlying coating may comprise a plasma-deposited polymer.

In a preferred embodiment, the coating process is a vacuum deposition process. Such processes include physical vapour deposition (PVD), chemical vapour deposition (CVD), plasma chemical vapour deposition (PCVD), plasma-enhanced chemical vapour deposition (PECVD) and/or plasma-assisted chemical vapour deposition (PACVD). When using vacuum deposition processes used for providing the overlying coating, it is preferred that any air (or other gas) bubbles are minimized within the masking plug as the vacuum used for providing the overlying coating can cause the bubbles to expand and thereby distort, dislodge and/or rupture the masking plug.

Techniques for forming a plasma-deposited coating are known in the art, and have been previously identified as providing particularly effective coatings to protect PCBs and their components from damage from contaminants such as water (as described, for example, in WO 2007/083122, WO 2016/198855, WO 2016/198957 or WO 2020/169975). Suitably, the coating process may be as claimed in any of these publications, which are incorporated herein by reference. Particularly preferred embodiments of these plasma coating methods are set out below.

In a preferred embodiment, the monomer compound comprises an acrylate monomer. It is particularly preferred that the acrylate monomer is selected from 1H,1H,2H,2H-pefluorohexyl methacrylate (PFMAC4), 1H,1H,2H,2H-perfluorooctyl methacrylate (PFMAC6), 1H,1H,2H,2H-perfluorodecyl methacrylate (PFMAC8), or benzyl acrylate. While any of these acrylates can be used in combination with other monomers in the coating process, including other acrylates from the above list, it is preferred that any given monomer is the sole monomer used for plasma polymerisation.

In a particularly preferred embodiment, the coating process additionally comprises submitting a crosslinking agent to the plasma polymerisation and deposition process. By this, we mean that the coating process comprises submitting a monomer compound and a crosslinking agent to the plasma polymerisation and deposition process. The crosslinking agent can further improve the barrier properties of the overlying coating. The crosslinking agent is preferably selected from divinyl adipate (DVA), 1,4-butanediol divinyl ether (BDVE), 1,4-cyclohexanedimethanol divinyl ether (CDDE), 1,7-octadiene (17OD), 1,2,4-trivinylcyclohexane (TVCH), 1,3-divinyltetramethyldisiloxane (DVTMDS), diallyl 1,4-cyclohexanedicarboxylate (DCHD), 1,6-divinylperfluorohexane (DVPFH), 1H,1H,6H,6H-perfluorohexanediol diacrylate (PFHDA), and/or glyoxal bis (diallyl acetal) (GBDA).

As the coating can provide protective properties against contaminants, the masking material does not necessarily need to be resistant to contaminants. However, in case the coating is compromised, it may be desirable for the masking material to provide a second level of defence against contaminants. In a preferred embodiment the masking material is a barrier material and/or electrically insulating. In particular, it is preferred that the masking material is water resistant.

### Removal

In one embodiment, the method comprises removing the elastic masking plug. The method of removal can be any method that removes the elastic masking plug without damaging the RF switch. In some embodiments, removal can be done by pulling the elastic masking plug from the receptacle. It is generally preferred that the elastic masking plug is removed out of the probe access port. In some embodiments, the elastic masking plug is removed out of the probe access by a pulling force applied to the elastic masking plug. The elastic masking plug can be removed out of the probe access port without damaging the RF switch by a pulling force applied to the elastic masking plug. Any suitable means for applying a pulling force to the elastic masking plug may be used. In some embodiments, removal can be done by using a removal implement, such as tweezers or a pick, to manipulate the elastic masking plug and pull it from the receptacle. Where the elastic masking plug has a protrusion, using a removal implement to hold the protrusion can assist with ease of removal. In one embodiment the removal is automated. In some embodiments, removal can be conducted by exerting a twisting force in addition to a pulling force. A twisting force can help dislodge the masking plug. After removal, correct functioning of the RF switch can be examined by checking conductivity across the switch and by checking correct interfacing with a test probe. In some embodiments a discrete test of RF switch function can be omitted, and the PCB unit is simply submitted directly to the probe test. If masking is needed subsequent to removal of the masking plug, for instance after any testing using a test probe is conducted, a masking plug can be reapplied.

### Masked RF Switch and PCBs

According to a second aspect, the invention provides a masked RF switch producible, preferably produced, according to the first aspect.

According to a third aspect, the invention provides a masked PCB-mounted RF switch comprising a receptacle, the receptacle comprising a probe access port, one or more side ports, and an electromechanical component therein and the receptacle being shaped for receiving a probe through the probe access port to actuate the electromechanical component, and wherein the receptacle and the one or more side ports further comprise an elastic masking plug that is removable.

The masked RF switch of the third aspect may comprise any or all of the features of the first aspect.

A preferred embodiment of the third aspect is an RF switch that further comprises an overlying coating. In this embodiment, the overlying coating is over the RF switch and the masking plug. In a particularly preferred embodiment, the overlying coating is a water-resistant barrier. In a yet more preferred embodiment, the overlying coating is a plasma-deposited polymer.

According to a fourth aspect, the invention provides an RF switch according to the second or third aspect, therein the masking plug has been removed.

According to a fifth aspect, the invention provides a printed circuit board (PCB) or printed circuit board assembly (PCBA) comprising an RF switch according to the second, third or fourth aspects of the invention.

In a preferred embodiment, the PCBA is for small portable electronic devices such as mobile phones, smartphones, pagers, radios, hearing aids, laptops, notebooks, tablet computers, phablets and personal digital assistants (PDAs). These types of devices can be exposed to significant liquid contamination when used outside or inside in close proximity of liquids. Such devices are also prone to accidental exposure to liquids, for example if dropped in liquid or splashed.

### General

Throughout the description and claims of this specification, the words “comprise” and “contain” and variations of the words, for example “comprising” and “comprises”, mean “including but not limited to”, and do not exclude other components, integers or steps. Moreover the singular encompasses the plural unless the context otherwise requires: in particular, where the indefinite article is used, the specification is to be understood as contemplating plurality as well as singularity, unless the context requires otherwise.

Preferred features of each aspect of the invention may be as described in connection with any of the other aspects. Within the scope of this application it is expressly intended that the various aspects, embodiments, examples and alternatives set out in the preceding paragraphs, in the claims and/or in the following description and drawings, and in particular the individual features thereof, may be taken independently or in any combination. That is, all embodiments and/or features of any embodiment can be combined in any way and/or combination, unless such features are incompatible.

### BRIEF DESCRIPTION OF THE DRAWINGS

One or more embodiments of the invention will now be described, by way of example only, with reference to the accompanying drawings, in which:

FIG. 1a is a simplified cross-section schematic of a normally-closed momentary-action RF switch in the absence of a probe,

FIG. 1b is a simplified cross-section schematic of the RF switch of FIG. 1 where it has been actuated by a probe,

FIG. 2 is a perspective-view schematic drawing of a typical RF switch.

FIG. 3 is a cutaway perspective drawing of the RF switch of FIG. 2,

FIG. 4 is a cutaway side-view drawing of the RF switch of FIG. 2 showing a masking plug in place,

FIG. 5a is a photograph of a test PCB having an RF switch thereon,

FIG. 5b is a close-up photograph of the RF switch of FIG. 5a,

FIG. 6a is an RF switch protected by a rubber grommet and silicone seal,

FIG. 6b is an RF switch similar to that of FIG. 6a, showing a failure after exposure to vacuum,

FIG. 7 is a flow diagram showing photographs at various steps of protecting an RF switch with a masking plug, plasma coating and then removing the masking plug,

FIG. 8 is a close-up photograph of the removed masking plug,

FIG. 9 shows SEM images of the switch plates of RF switches after applying a masking plug, plasma coating, and then removing the masking plug,

FIG. 10 is a chart showing electrical resistance through RF switches when untreated, with masking plug, and after removal of masking plug, and

FIG. 11 is a chart showing water-test resistance measurements of RF line to induction shielding when untreated, with masking plug, and with masking plug and coating.

### DETAILED DESCRIPTION

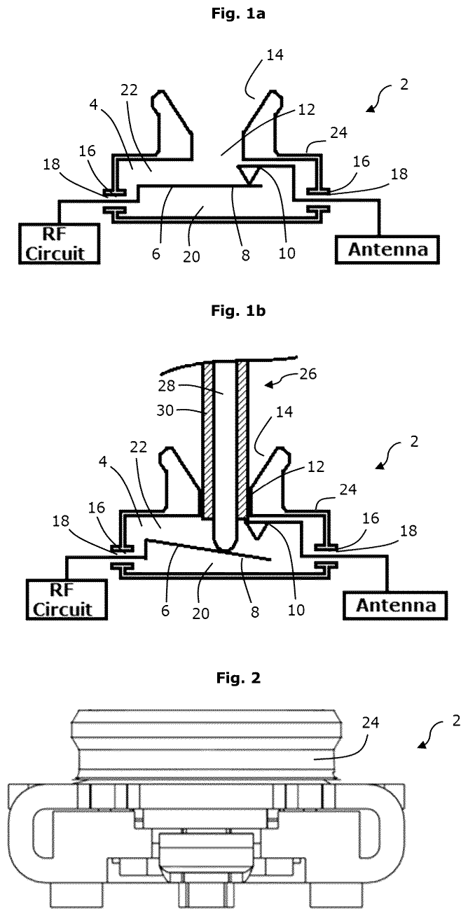

FIGS. 1a and 1b show a simplified illustration of an embodiment of an RF switch 2. In this embodiment, the RF switch 2 comprises a receptacle 4. Within the receptacle 4 is an electromechanical component 6, which in this embodiment is a switch plate 8. The switch plate 8 is biased such that in the absence of an external force the switch plate 8 is in contact with a switch plate connector 10. The receptacle 2 also comprises a probe access part 12 and a probe guide 14. The probe guide 14 has a concave cone shape. The receptacle 2 also comprises side ports 16. The side ports have side port access channels 18. Also shown is an interstice 20. It can be seen that the RF switch has internals 22 and externals 24. In FIGS. 1a and 1b, the switch plate 8 is connected to the RF circuit and the switch plate connector 10 is connected to the antenna. Depending on the design of the RF switch 2, this could be reversed.

FIG. 1a shows the RF switch 2 in the absence of a probe. The switch plate 8 is therefore in contact with the switch plate connector 10. FIG. 1b shows the RF switch 2 upon actuation by a probe 26. The probe 26 has a probe core 28 that has actuated the switch plate 8 and broken the connection between the switch plate 8 and the switch plate connector 10. The probe core 28 has also formed an connection with the switch plate 8, whereby if the probe core 28 were conductive then this would be an electric connection through which electric signals could be passed to/from the RF circuit. The probe 26 also has a probe sheath 30. In the embodiment shown in FIG. 1b the probe sheath 30 contacts the switch plate connector 10. In an embodiment where the probe core 28 were insulating and the probe sheath 30 were conducting, it can be seen how the probe 26 could be designed to form an electric connection with the switch plate connector 10 such that electric signals could be passed to/from the antenna.

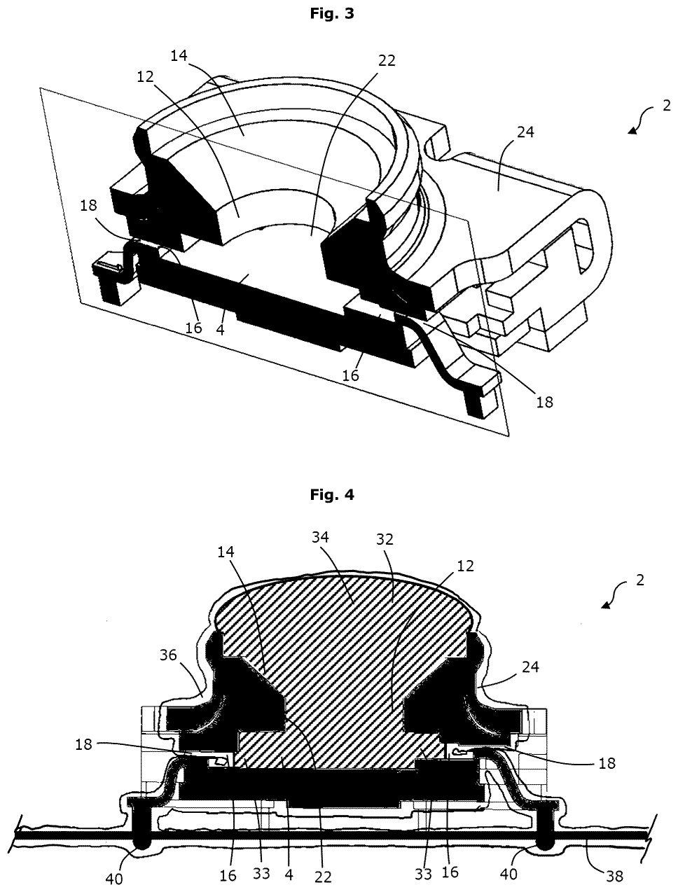

FIG. 2 shows a side view line diagram that represents an actual RF switch 2.

FIG. 3 is a perspective view of the RF switch 2 of FIG. 2, with a cut-away section so that the interior of the RF switch 2 can be seen in more detail. In FIG. 3, the switch plate and switch plate connector are not shown for clarity. It can be seen that the probe guide 14 has a concave cone shape, leading to the probe access port 12. It can be seen that if an off-target probe is lowered into the RF switch 2, as long as it will still be captured by the probe guide 14, then the probe guide 14 will redirect the probe in the x-y plane (i.e. the plane of the PCB) to target the probe access port 12. This increases the tolerances of targeting the probe prior to lowering into the RF switch 2 and into the RF switch receptacle 2.

FIG. 3 also shows the side access ports 16 and the side access port channels 18. It can be seen that the side access port channels 18 have multiple sections that narrow in the direction from the interior to the exterior of the RF switch 2.

FIG. 4 shows the RF switch 2 of FIGS. 2 and 3 connected to a PCB (38) by solder joints (40). In addition, the hatched area of FIG. 4 shows the region occupied by the masking plug 32 (or the curable masking material if it is prior to curing). The masking plug 32 is in the receptacle 4, has a protrusion 34 and extends into the side port channels 18. FIG. 4 also shows an overlying coating 36, that covers the RF switch externals 24, the masking plug 32, portions of the side port channels 18 that do not contain masking material 32, the PCB 38 and the solder joints 40. However, the internals 22 of the RF switch 2, in particular the receptacle 4, do not have coating 36.

### EXAMPLES

### Test PCBs Used in the Examples

Unless otherwise stated, test PCBs prepared according to the following protocol were used in the subsequent examples.

Test PCBs comprising RF switches were prepared, utilising a Murata SWH-2Way MM8930-2620 RF switch soldered onto a Si wafer having metal tracks of gold coated copper for testing the RF switch circuitry.

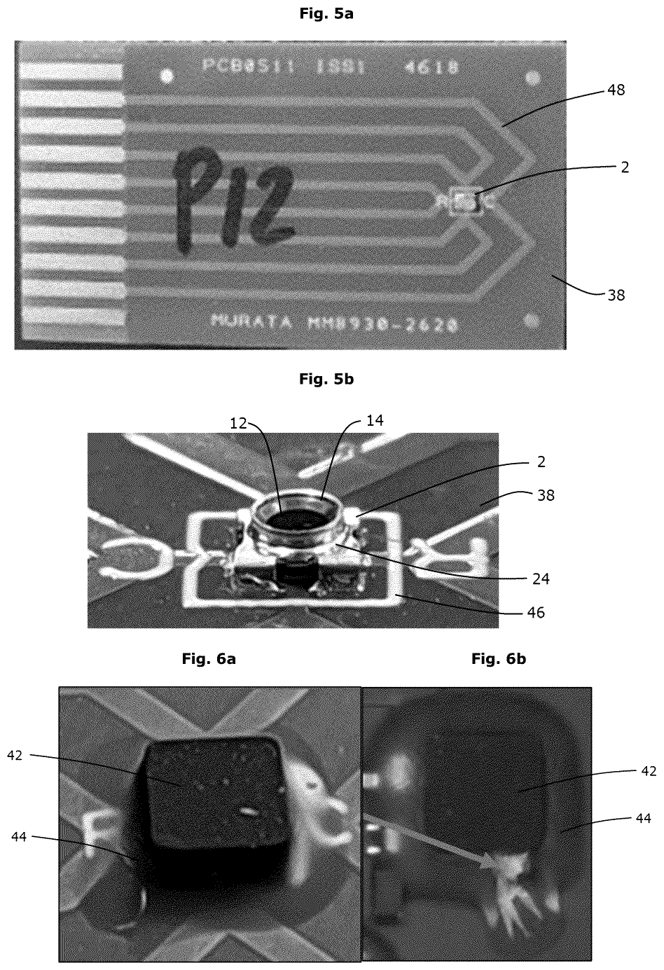

FIG. 5a shows the construction of the test PCBs 38, showing electric tracks 48 by which the RF switch 2 can be put under conditions to mimic end-user requirements and/or test requirements. A close-up photograph of the RF switch 2 is shown in FIG. 5b. In FIG. 5b, the externals 24 of the RF switch can be seen, as well as the probe guide 14 and probe access port 12. The white line 46 around the RF switch 2 is the ‘keep-out’ line and represents the boundary for where the RF switch can be placed so as not to affect other components on a PCB array.

### Plasma Deposition Process Used in the Examples

Unless otherwise stated, the following plasma deposition technique was used in the following examples.

Plasma polymerization experiments were carried out in a metallic reaction chamber with a working volume of 22 litres. The chamber consisted of two parts, a shallow cuboid cavity with a single open face, oriented vertically, which was sealed to a solid metallic door via a Viton O-ring on the outer edge. All surfaces were heated to 37° C. Inside the chamber was a single perforated metal electrode, area per the open face of the cavity, also oriented vertically and attached via connections at the corners to the door, fed by an RF power unit via a connection through the centre of the metallic door. For pulsed plasma deposition the RF power unit was controlled by a pulse generator.

The rear of the chamber was connected via a larger cavity, achieving a total volume of 125 L, to a metal pump line, pressure controlling valve, a compressed dry air supply and a vacuum pump. The door of the chamber comprised several cylindrical ports for connection to pressure gauges, monomer delivery valves (inner surfaces of which were heated to 70° C.), temperature controls and gas feed lines which were in turn connected to mass flow controllers.

In each experiment a sample was positioned vertically on nylon pegs attached to the perforated electrode, facing the door.

The reactor was evacuated down to base pressure (typically <10 mTorr). Process gas was delivered into the chamber using the mass flow controllers, with typical gas flow values being between 2-25 sccm. The monomer was delivered into the chamber, with typical monomer gas flow values being between 5-60 sccm. The chamber was heated to 37° C. The pressure inside the reactor was maintained at between 20-30 mTorr. The plasma was produced using RF at 13.56 MHz. The process usually contains at least the steps of a continuous wave (CW) plasma and a pulsed wave (PW) plasma. Optionally, these steps can be proceeded by an initial activation step using a continuous wave (CW) plasma. The activation CW plasma, if used, was for 1 minute, the CW plasma was for 1 or 4 minutes and the duration of the PW plasma varied in different experiments. The peak power setting was 160 W in each case, and the pulse conditions were time on (tₒₙ)=37 μs and time off (t_{off})=10 ms. At the end of the deposition the RF power was switched off, the monomer delivery valves stopped and the chamber pumped down to base pressure. The chamber was the vented to atmospheric pressure and the coated samples removed.

The monomer compound used in these examples was 1H,1H,2H,2H-perfluorooctylacrylate (PFAC6) (CAS #17527-29-6). The crosslinking agent used in these examples was divinyl adipate (DVA) (CAS #4074-90-2).

A 2500 nm thick coating was deposited onto printed circuit boards (PCBs) and accompanying RF switches in the gas phase plasma deposition process described above, using PFAC6 and DVA, which were introduced to the plasma deposition chamber in the liquid phase, pre-mixed at the volumetric ratio 9:1.

### Analytical Methods

### Resistance in Tap Water

This test method has been devised to evaluate the ability of different coatings to provide an electrical barrier on printed circuit boards and predict the ability of a smart phone to pass the IEC 60529 14.2.7 (IPX7) test. The method is designed to be used with tap water. This test involves measuring the current voltage (IV) characteristics of a test PCB described above in water. Conductivity is measured between the RF line and the induction shielding of the RF switch (two surfaces that are meant to have a high resistance between them). The degree of electrochemical activity is quantified by measuring current flow; low current flow is indicative of a good quality coating.

The PCB to be tested is placed into a beaker of water and connected to the electrical test apparatus. The board is centred horizontally and vertically in the beaker to minimise effects of local ion concentration. When the PCB is connected, the power source is set to the desired voltage and the current is immediately monitored. The voltage applied is for example 8V and the PCB is held at the set voltage for 13 minutes, with the current being monitored continuously during this period.

The coatings formed by the different process parameters are tested.

### Coating Thickness

The thickness of the coatings formed can be measured using spectroscopic reflectometry apparatus (Filmetrics F20-UV) using optical constants verified by spectroscopic ellipsometry.

### Spectroscopic Ellipsometry

Spectroscopic ellipsometry is a technique for measuring the change in polarization between incident polarized light and the light after interaction with a sample (i.e. reflected, transmitted light etc). The change in polarization is quantified by the amplitude ratio ψ and phase difference Δ. A broad band light source is used to measure this variation over a range of wavelengths and the standard values of ψ and Δ are measured as a function of wavelength. The ITAC MNT Ellipsometer is an AutoSE from Horiba Yvon which has a wavelength range of 450 to 850nm. Many optical constants can be derived from the ψ and Δ values, such as film thickness and refractive index.

Data collected from the sample measurements includes the intensities of the harmonics of the reflected or transmitted signal in the predefined spectral range. These are mathematically treated to extract intensity values called Is and Ic as f(I). Starting from Ic and Is the software calculates ψ and Δ. To extract parameters of interest, such as thickness or optical constants, a model has to be set up to allow theoretical calculation of ψ and Δ. The parameters of interest are determined by comparison of the theoretical and experimental data files to obtain the best fit (MSE or X²). The best fit for a thin layer should give an X²<3, for thicker coatings this value can be as large as 15. The model used is a three layer Laurentz model including PTFE on Si substrate finishing with a mixed layer (PTFE+voids) to account for surface roughness.

### Spectroscopy Reflectrometry

Thickness of the coating can be measured using a Filmetrics F20-UV spectroscopy reflectrometry apparatus. This instrument (F20-UV) measures the coating's characteristics by reflecting light off the coating and analyzing the resulting reflectance spectrum over a range of wavelengths. Light reflected from different interfaces of the coating can be in- or out-of-phase so these reflections add or subtract, depending upon the wavelength of the incident light and the coating's thickness and index. The result is intensity oscillations in the reflectance spectrum that are characteristic of the coating.

To determine the coating's thickness, the Filmetrics software calculates a theoretical reflectance spectrum which matches as closely as possible to the measured spectrum. It begins with an initial guess for what the reflectance spectrum should look like, based on the nominal coating stack (layered structure). This includes information on the thickness (precision 0.2 nm) and the refractive index of the different layers and the substrate that make up the sample (refractive index values can be derived from spectroscopic ellipsometry). The theoretical reflectance spectrum is then adjusted by adjusting the coating's properties until a best fit to the measured spectrum is found.

Alternative techniques for measuring thickness are stylus profilometry and coating cross sections measured by SEM.

### Testing RF Switch Conductivity Across Switch

This tests conductivity across the RF switch. Failure of this test may indicate that the RF switch has been stuck in an open position or otherwise damaged such that current cannot pass through the switch. This can be measured by ohmmeter. A resistance of higher than 70 mOhms is considered a fail.

### Analysing Chemical Composition of Surface by SEM+EDX

Scanning electron microscopy combined with energy dispersive X-ray spectroscopy (SEM+EDX) can be used to generate detailed pictures of microscopic surface structures as well as provide accurate information about the elemental composition of the surface. These techniques are well-known in the art and can be conducted using commercially available equipment. The present analyses were conducted using a Phenom XL Desktop Scanning Electron Microscope, With a sample size of 100 mm×100 mm and EDX system.

This technique can assess plasma coating by analysing for fluorine on the component surface. While the relationship between EDX detected fluorine content (%) of surface and coating thickness is not necessarily linear in correlation, the following has been correlated. Full exposure to plasma coating displays ˜30+% fluorine content. Partial, non-uniform or thin coatings will appear between 8-30% fluorine. Ultrathin non-uniform coatings will appear between 0.1-8% fluorine. Prior to plasma coating the switch plates of the RF switches displayed 0% fluorine content.

This technique visualises how much of the RF switch and its components have been coated in an insulating layer. According to this test, as long as areas of the RF switch that are required for electrical connections with a test probe are not coated, the masking/coating/demasking process has been successful and the RF switch can be relied on in a re-work cycle.

### Example PCB Manufacture Process

1. PCB assembly leaves Surface Mount Technology (SMT) factory or floor fully assembled.
2. PCB assembly programming is performed.
3. PCB assembly functionality testing is completed (correct operation of RF switch in absence of test probe is used).
4. PCB assembly OTA testing is completed (correct functioning of RF switch under test probe contact conditions is used).
5. PCB assembly is loaded into a holding fixture.
6. A robot mounted dispensing pen injects curable masking material into the RF switch.
7. PCB assembly is exposed to UV at an appropriate wavelength to cure the masking material to form a masking plug.
8. PCB assembly is plasma coated. The masking plug prevents plasma reaching electrical surfaces needed for probe interface from multiple access ports.
9. PCB assembly is dispatched for onward assembly.
10. [Optional] If a test step is required for board level or device level OTA testing
   a. Tweezers or pick can be used to grip the masking plug and gently dislodge the masking plug from the RF switch.
   b. If water protection is deemed necessary after the test, masking can be redone.
11. End product released for commercial use.
12. Re-work cycle. OTA testing required during a re-work cycle can be performed by removing the masking plug from the RF switch.
   a. Tweezers or pick can be used to grip the masking plug and gently dislodge the masking plug from the RF switch.
   b. If water protection is deemed necessary after the test, masking can be redone.

### Example 1—Rubber Grommet

FIG. 6a shows an attempt to mask an RF switch by applying a rubber grommet 42 over the RF switch and sealing the grommet 42 to the PCB using a ring fence of silicone seal 44. It can be seen that the keep-out line 46 has been crossed by the grommet 42, and has been crossed to a greater extent by the seal 44. Additionally, it was not straightforward to apply the silicone sealant ring-fence 44, requiring careful manual application from multiple angles and/or positions while holding the rubber grommet 42 in place to prevent slippage. It would not be straightforward to automate this.

FIG. 6b shows a similar setup, whereby the test PCB has been subjected to the plasma deposition technique outlined above. It can be seen that the silicone seal 44 has failed under vacuum. The air trapped under the grommet 42 has forced its way out through the silicone seal 44. Plasma had entered the rubber grommet 42 by means of this failure and deposited a coating layer within the RF switch. F content levels of 2.5-25% atomic composition were detected using SEM+EDX.

### Example 2—Silicone Rubber Mask

Silicone rubber blend with a viscosity of 42,000 cP (as per ISO 3219 at D=0.5) was flowed into an RF switch receptacle and cured in place using broadband ultraviolet light to form a silicone rubber mask with a cured hardness that is too soft to be measured on the Shore Hardness Scale (using ASTM D2240-15). The cured hardness was measured to be 50-70 1/10 mm (DIN ISO 2137 SUR Penetrometer). The modulus of elasticity of the silicone rubber mask was indicated to be less than 50 kPa, and to fall within the range 5-50 kPa (ASTM D0638-22). The silicone rubber mask was then removed and visually inspected, and resistance measured. Initial resistance tests suggested this approach works. However, visual inspection revealed that not all of the mask was removed and visible silicone rubber contamination was left in place. This could be problematic in situations where probe contamination would be unacceptable. It was difficult to clean the remaining silicone rubber out of the RF switch without damage. Given how small RF switches are, how thin the metal housing is, and how thin the RF switch mechanism is, they are too small and delicate to clean with existing tools. Mechanisms of failure include bending in the switch plate causing errant readings, and torsion on the RF switch cracking the solder joints.

### Example 3—RF Switch Masking, Coating and Mask Removal

A test PCB having an RF switch was provided. The PCB was mounted into a holding fixture that provides a precision location for delivery of the curable masking material. As a curable masking material, urethane-acrylate having a viscosity defined by ASTM D2556-14 of 50,000 cP at 20 rpm, 20 deg C. and 1 atm was selected. A robot mounted dispensing pen injected the curable masking material into the receptacle of the RF switch. The amount of curable masking material was selected to match the size of the RF switch so as to fill the receptacle and provide a protrusion above the RF switch while not overflowing the sides of the RF switch.

The curable masking material was cured using an ultraviolet LED lamp (385 nm Wavelength; 3000 mJ/cm2—Intensity; 5 second exposure time) to cure the masking material in place to form a masking plug. The masking plug had a hardness of Shore A75, was not soluble in water and exhibited low water absorption. The masking material had the following properties:
Durometer Hardness: A75 (ASTM D-2240-15)
Elongation at break: 100% (ASTM D-0638-22)
Tensile at break: 500 psi (ASTM D-0638-22)
Modulus of elasticity: 800 psi (ASTM D-0638-22)

Where required, a plasma coating was applied using the standard procedure as set out above.

Where required, the masking plug was removed by gripping the protrusion with tweezers and pulling out using a twisting and/or peeling motion to gently dislodge the masking plug from the RF switch.

### Flow Chart

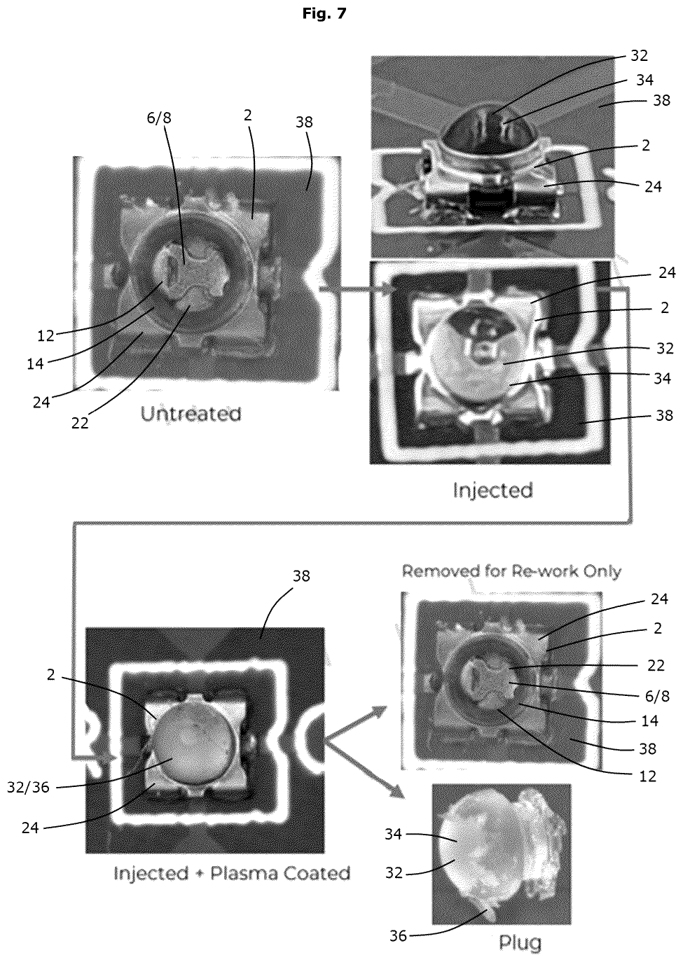

FIG. 7 shows a flow chart of an embodiment of the invention in the form of photographs of each stage. An untreated RF switch 2 is shown in the first photograph (labelled “Untreated”), and the switch plate 8 is clearly visible. The RF switch 2 was then treated by injecting a urethane-acrylate curable masking material and curing in place using ultraviolet light to form an elastic masking plug 32. The masking plug 32 has a dome-shaped protrusion 34 above the RF switch 2, but no masking plug 32 is present on the RF switch externals 24 (labelled “Injected”). The whole assembly (PCB 38, RF switch 2, and masking plug 32) was then coated using plasma-deposition to provide a plasma-deposited overlying coating 36 (labelled “Injected+Plasma Coated”). In the final stage, the masking plug 32 was removed from the RF switch 2 by using tweezers to hold and pull the protrusion 34. The switch plate 8 can again be seen (photograph labelled “Removed for Re-work Only”) and the removed masking plug 32 is also shown (photograph labelled “Plug”).

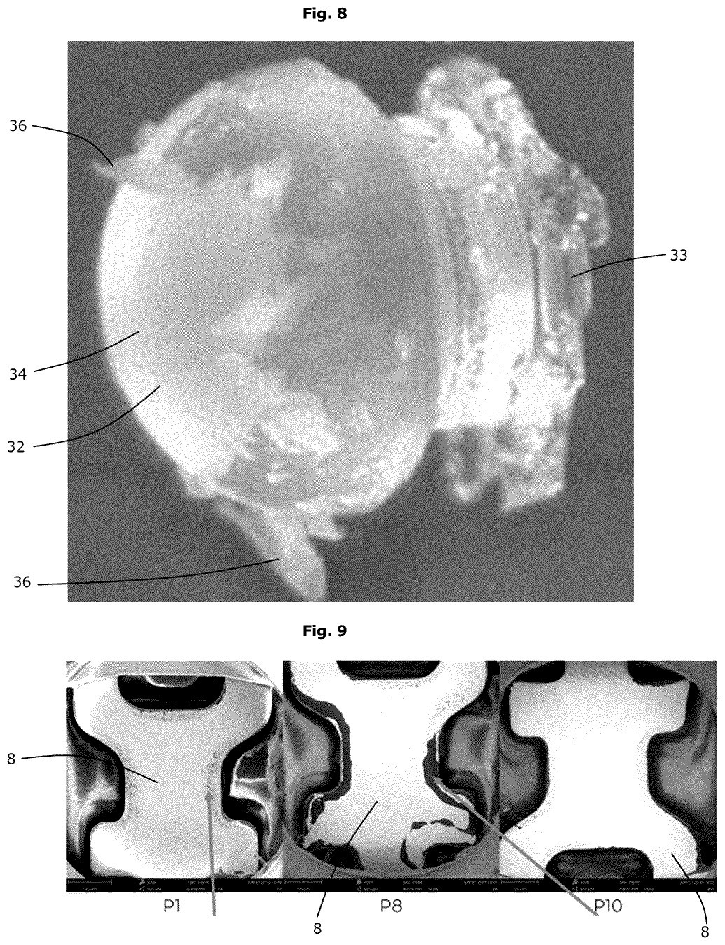

FIG. 8 shows an enlarged photograph of the removed masking plug 32. This shows where the overlying coating 36 has been peeled away from the masking plug 32 during removal. The removed masking plug 32 has been removed in one piece and retains the shape it had inside the RF switch. Projections 33 show where the masking plug 32 occupied side port channels and other interstices in the RF switch receptacle. This also shows how the masking plug 32 must flex during removal through the probe access port 12.

### Test 1—Removal of Masking Plug

This test analysed ease of removal and residue. This test was replicated 60 times. The following results were achieved.
Masking plug removes on first attempt—all 60/60 of the tests.
Masking plug removes in one piece—all 60/60 of the tests.
Analysis of residue or detritus was conducted by optical microscope and SEM+EDX. No residue or detritus detected—all 60/60 of the tests.

It was noted that the masking plug retained the shape of the RF switch interior in all cases. The impression of the electromechanical switch components could be clearly seen on the base of the masking plug. The base of the masking plug also had protrusions representing where the curable masking material had flowed into interstices within the RF switch.

### Test 2—Plasma Coating of RF Switch Internals

This test analysed for plasma coating within the RF switch after removal of the masking plug. This test checks the utility of the masking plug in preventing the plasma from accessing the electromechanical components within the RF switch. This test utilised the analysis for plasma coating by SEM+EDX as described above. This test was replicated 60 times. The following results were achieved.

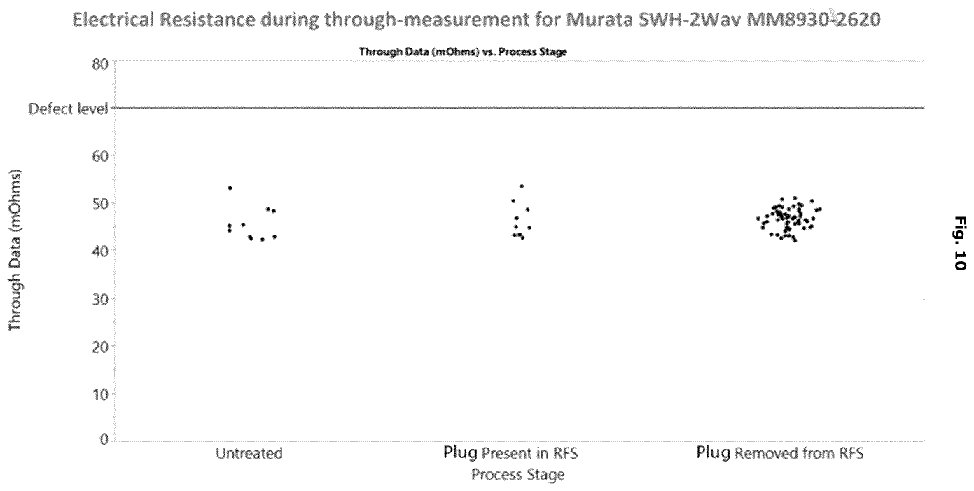

In no cases were the electromechanical components fully coated. Several examples had veins of coating toward the edges of the switch plate, wherein the veins had an F content of between 2.5-15% atomic composition (see FIG. 9). This coating was not in the target area for the test probe, and therefore was not sufficient to block correct function of the RF switch when in contact with a test probe.

The plasma coating on electromechanical components within the RF switch were within acceptable levels for all 60/60 of the tests.

### Test 3—Electrical Performance of RF Switch Under Consumer Use Conditions

This test analysed electrical performance of the RF switch under consumer use conditions. The resistance test as described above was used. Specifically, this test measures resistance across RF switch after curing and coating (i.e. prior to removal of masking plug) and again after removal of the masking plug. In all cases, the switch is left in the neutral position adopted by the switch after each step. This test determines if the RF switch is still in a state where the antenna would be connected to the RF circuitry, as is required for correct function in the unit as used by the end consumer. The test is regarded as a fail if the resistance rises above 70 mOhms (i.e. this represents that the connection between the antenna and RF circuit would be broken, if this was a real-world PCB rather than a test PCB).

This test was replicated 60 times.

As shown in the table of FIG. 10, the electrical performance of the RF switch was not compromised by addition and curing of the curable masking material, or by subsequent removal of the masking plug. This test was passed, at both stages, by all 60/60 of the tests.

### Test 4—Resistance to Water Exposure

This test comprised exposing the test PCBs to water and assessing impacts of water damage. The PCB/RF switch was connected to a power supply to mimic electrical loads under consumer use conditions. The RF switch was submerged under water and 8V was applied for 13 minutes. The electrical resistance of the RF switch was then tested.

The following were tested.
Untreated RF switch (uncoated and unplugged; UCUP), 2 replicates.
Masking plug only (uncoated and plugged; UCP), 3 replicates.
Masking plug and plasma coated (coated and plugged; CP), 5 replicates.

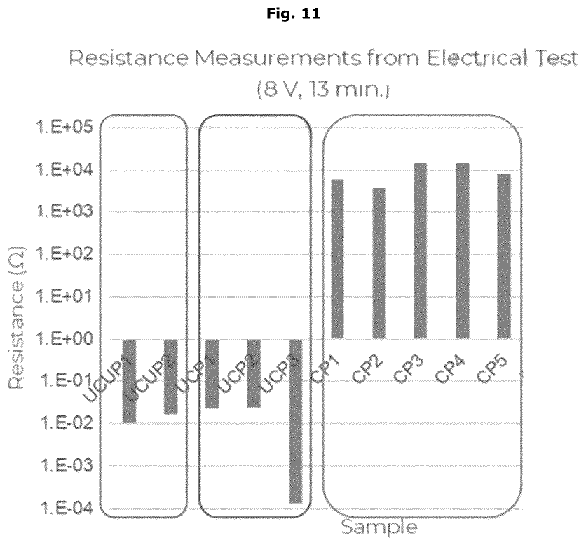

The masking plug and/or plasma coating were applied as set out above. The results of the tests are shown in FIG. 11.

As expected, in the absence of the coating (UCUP and UCP), the RF switch suffered water damage. In addition, visual inspection revealed that the UCUP test samples had the highest level of corrosion and electrochemical migration. Visual inspection of the UCP test samples showed corrosion products and electrochemical migration as well—though the internals were protected to some extent by the masking plug.

The test samples that were both plugged and plasma coated (CP) gave the highest resistances of around 10 kOhm by the end of the 13 minutes of applied voltage. Visual inspection showed no signs of corrosion or electrochemical migration.

This shows that the plasma coating is required to provide water protection.

### Example 4—Further Masking Materials

A Further masking material was produced using urethane acrylate having 1-5 wt % fumed silica. This gave the following properties:
Durometer Hardness: A75 (ASTM D2240-15)
Elongation at break: 140% (ASTM D0638-22)
Tensile at break: 490 psi (ASTM D0638-22)
Modulus of elasticity: 600 psi (ASTM D0638-22)

It was found that this material is significantly more thixotropic that the material of Example 2. This allowed for improvements in handling and dispensing. Formation of a protrusion was observed to form a cone, whereas the material of Example 3 formed a dome. This material performed acceptably for RF switch masking.

### Example 5—Further Masking Materials

A Further masking material was produced using urethane acrylate having 10-24 wt % N,N-dimethylacrylamide. This gave the following properties:
Durometer Hardness: A50
Tensile at break: 1160 psi

This material performed acceptably for RF switch masking.

1. A method of masking a PCB-mounted radiofrequency switch for a subsequent coating process, wherein the radiofrequency switch comprises a receptacle comprising a probe access port and one or more side ports, the receptacle having an electromechanical component therein, and the receptacle being shaped for receiving a probe through the probe access port to actuate the electromechanical component, wherein the method comprises flowing a curable masking material into the probe access port and thereby through the receptacle into the one or more side ports, and curing the masking material to form a removable elastic masking plug.

2. The method according to claim 1, wherein the receptacle is defined by internals of the radiofrequency switch, and wherein externals of the radiofrequency switch are kept substantially free from masking material.

3. The method according to claim 1, Wherein the elastic masking plug is removable out of the probe access port by a pulling force applied to the elastic masking plug.

4. The method according to claim 1, wherein the receptacle comprises one or more interstices, and the method comprises flowing the masking material into the interstices.

5. The method according to claim 1, wherein the elastic masking plug comprises substantially the entirety of the masking material flowed into the receptacle and is removable substantially in one piece.

6. The method according to claim 1, wherein the elastic masking plug is formed with a protrusion into one or more side ports.

7. The method according to claim 1, wherein the elastic masking plug has a hardness defined by ASTM D2240-15 of Shore A30 to A100, preferably Shore A40 to A90, more preferably Shore A50 to A80.

8. The method according to claim 1, wherein the elastic masking plug has a modulus of elasticity defined by ASTM D0638-22 of 300-2000 psi, preferably 400 to 1000 psi, more preferably 500 to 900 psi, yet more preferably 600 to 800 psi.

9. (canceled)

10. The method according to claim 1, wherein the curable masking material comprises urethane acrylate.

11. The method according to claim 1, the curable masking material has a viscosity defined by ASTM D2556-14 of 20,000-140,000 cP at 20 rpm, 20 deg C. and 1 atm, preferably 40,000-120,000 cP at 20 rpm, 20 deg C. and 1 atm, more preferably 60,000-100,000 cP at 20 rpm, 20 deg C. and 1 atm.

12. The method according to claim 1, wherein the curable masking material is thixotropic.

13. (canceled)

14. The method according to claim 1, wherein the receptacle is a coaxial receptacle.

15. The method according to claim 1, wherein the method comprises the step of the subsequent coating process, wherein the coating process comprises depositing an overlying coating over the radiofrequency switch and elastic masking plug.

16. The method according to claim 15, wherein the overlying coating is a water-resistant-and/or electrically insulating barrier.

17. The method according to claim 15, wherein the coating process comprises submitting a monomer compound to a plasma polymerisation and deposition process to form a plasma-deposited overlying coating.

18. The method according to claim 17, wherein the monomer compound comprises an acrylate monomer, preferably wherein the acrylate monomer is selected from 1H,1H,2H,2H-pefluorohexyl methacrylate (PFMAC4), 1H,1H,2H,2H-perfluorooctyl methacrylate (PFMAC6), 1H,1H,2H,2H-perfluorodecyl methacrylate (PFMAC8), and/or benzyl acrylate.

19. The method according to claim 17, wherein the coating process additionally comprises submitting a crosslinking agent to the plasma polymerisation and deposition process, preferably wherein the crosslinking agent is selected from divinyl adipate (DVA), 1,4-butanediol divinyl ether (BDVE), 1,4-cyclohexanedimethanol divinyl ether (CDDE), 1,7-octadiene (17OD), 1,2,4-trivinylcyclohexane (TVCH), 1,3-divinyltetramethyldisiloxane (DVTMDS), diallyl 1,4-cyclohexanedicarboxylate (DCHD), 1,6-divinylperfluorohexane (DVPFH), 1H,1H,6H,6H-perfluorohexanediol diacrylate (PFHDA), and/or glyoxal bis(diallyl acetal) (GBDA).

20. (canceled)

21. (canceled)

22. A masked PCB-mounted radiofrequency switch comprising a receptacle, the receptacle comprising a probe access port, one or more side ports, and an electromechanical component therein and the receptacle being shaped for receiving a probe through the probe access port to actuate the electromechanical component, and wherein the receptacle and the one or more side ports further comprise an elastic masking plug that is removable.

23. (canceled)

24. The masked radiofrequency switch according to claim 22, further comprising an overlying coating, preferably wherein the overlying coating is a water-resistant barrier.

25. (canceled)

26. The masked radiofrequency switch according to claim 24, wherein the overlying coating is obtainable by submitting a monomer compound to a plasma polymerisation and deposition process to form a plasma-deposited polymer.

27. (canceled)

28. (canceled)
